(19) United States
(12) Patent Application Publication
(10) Pub. No.: US 2012/0098561 A1
(43) Pub. Date: Apr. 26, 2012

(54) Test probe with dual switching probe tip

(75) Inventor: Po-Chao TAN, Zhonghe City (TW)

(73) Assignee: Brymen Technology Corporation

(21) Appl. No.: 12/908,988

(22) Filed: Oct. 21, 2010

(51) Int. Cl. G01R 1/067

(52) U.S. Cl. 324/755.01

(57) ABSTRACT

A test probe with a dual switching probe tip includes an insulating sheath, a conductive wire and a complex probe tip, and an end of the conductive wire is passed and connected into the insulating sheath. The complex probe tip includes a connecting section, and a first measuring head and a second measuring head extended in opposite directions from both ends of the connecting section respectively, and the first and second measuring heads are measuring heads of two different specifications and electrically connected with each other, and the connecting section is selectively combined with the insulating sheath, and the first measuring head is exposed from the insulating sheath or accommodated in the insulating sheath and electrically connected to the conductive wire. The probe tip can be switched and installed at the insulating sheath to extend the using life of the test probe or meet the requirements of fitting different specifications.

### FIELD OF THE INVENTION

The present invention relates to a test probe, in particular to a test probe with a dual switching probe tip used in a multi-meter.

### BACKGROUND OF THE INVENTION

Multi-meter is an electronic measuring instrument generally providing different measuring functions including the functions of an ammeter, a voltmeter, and an ohmmeter, and this is also known as a universal meter, a multi-purpose meter, or a multi-functional electric meter. Such instrument is usually operated together with one or more test probes for a connection and a measurement, and thus the instrument will not be restricted by the space and the using place, and it can be used extensively for measuring various types of electronic products.

A conventional test probe mainly includes a soft external sheath, a hard internal sheath, a conductive wire and a probe tip, and an end of conductive wire is passed into the hard internal sheath and electrically connected to an end of the probe tip, and another end of the probe tip is passed out and exposed from the hard internal sheath, and the soft external sheath is sheathed on the exterior of the hard internal sheath to form the test probe.

Although the conventional test probe has the function of measuring various types of electronic products, the probe tip is fixed onto the hard internal sheath directly, and the test probe will be unusable if the probe tip is worn out or damaged, and thus causing unnecessary wastes. Furthermore, the probe tips of this sort are applicable for a single specification or district only, and it is necessary to have test probes of another specification for the use in different districts or regions, and thus incurring a higher manufacturing cost for making different molds and a higher management cost for keeping the inventory and classifying products. Obviously, the conventional test probe requires improvements.

### SUMMARY OF THE INVENTION

Therefore, the present invention is to provide a test probe with a dual switching probe tip, and the test probe having the dual switching probe tips installed at an insulating sheath can extend the using life of the test probes and meet the requirements for various different specifications.

The present invention discloses a test probe with a dual switching probe tip, and the test probe comprises an insulating sheath, a conductive wire and a composite probe tip, wherein an end of the conductive wire is passed and connected into the insulating sheath, and the complex probe tip includes a connecting section and a first measuring head and a second measuring head extended in opposite directions from both ends of the connecting section, and the first measuring head and the second measuring head are electrically connected, and the first measuring head and the second measuring head are measuring heads of two different specifications, and the connecting section can be selectively combined with the insulating sheath, and the first measuring head can be exposed from the insulating sheath or accommodated in the insulating sheath and electrically connected to the conductive wire.

The present invention provides a test probe with a dual switching probe tip, and the test probe comprises an insulating sheath, a conductive wire and a complex probe tip, wherein an end of the conductive wire is passed and connected into the insulating sheath, and the complex probe tip includes a connecting section, and a first measuring head and a second measuring head extended in opposite directions from both ends of the connecting section, and the first measuring head and the second measuring head are electrically connected to each other, and the connecting section can be selectively combined with the insulating sheath, and the first measuring head can be exposed from the insulating sheath or accommodated in the insulating sheath and electrically connected to the conductive wire.

The present invention also achieves the following effects. The probe tip and the insulating sheath are connected with each other by threads to assure a secured positioning effect of the probe tip. An elastic connector is designed for providing a good electric connection contact of the probe tip with the conductive wire. The latch between the positioning pillar and the through hole is designed for preventing the probe tip from falling out from the insulating sheath easily.

### BRIEF DESCRIPTION OF THE DRAWINGS

FIG. 1 is an exploded view of a test probe including an insulating sheath, a conductive wire and an elastic connector in accordance with the present invention;

FIG. 2 is an exploded view of components as depicted in FIG. 1 and a probe tip in accordance with the present invention;

FIG. 3 is a cross-sectional view of an assembly of components as depicted in FIG. 2;

FIG. 4 is a cross-sectional view of the probe tip as depicted in FIG. 3 and combined with the insulating sheath from another direction;

FIG. 5 is a cross-sectional view of an assembly of a test probe in accordance with another preferred embodiment of the present invention;

FIG. 6 is a cross-sectional view of the probe tip as depicted in FIG. 5 and combined with the insulating sheath from another direction;

FIG. 7 is an exploded view of a test probe in accordance with a further preferred embodiment of the present invention;

FIG. 8 is a cross-sectional view of a test probe in accordance with another further preferred embodiment of the present invention;

FIG. 8A is a cross-sectional view of Section 8A-8A of FIG. 8; and

FIG. 9 is a cross-sectional view of the probe tip as depicted in FIG. 8 and combined with the insulating sheath from another direction.

### DESCRIPTION OF THE PREFERRED EMBODIMENTS

The technical characteristics and contents of the present invention will become apparent with the following detailed description accompanied with related drawings. The drawings are provided for the purpose of illustrating the present invention only, but not intended for limiting the scope of the invention.

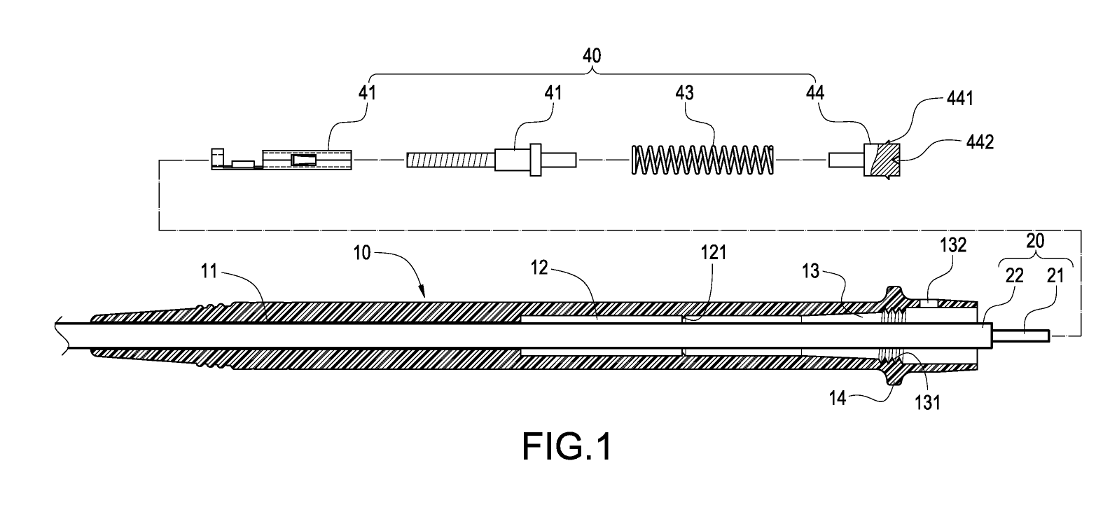

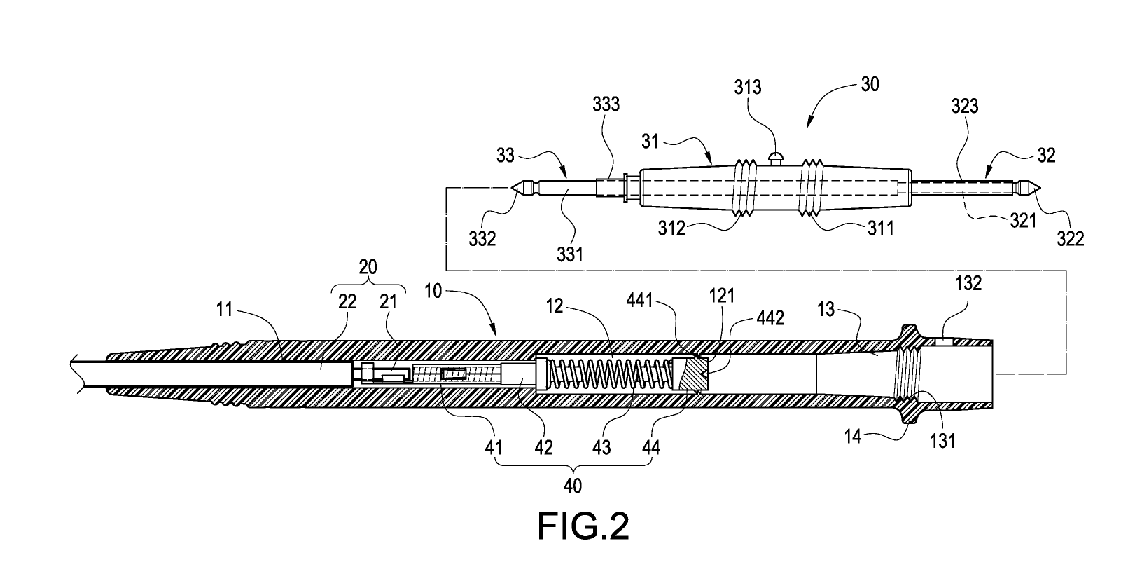

With reference to FIGS. 1 and 2, a test probe with a dual switching probe tip in accordance with the present invention comprises an insulating sheath 10, a conductive wire 20 and a complex probe tip 30.

The insulating sheath 10 is made of a highly insulating material such as plastic and substantially in the shape of a strip, and the interior of the insulating sheath 10 is comprised of a tubular first internal diameter 11, a tubular second internal diameter 12 greater than the first internal diameter 11, and a scalene conical third internal diameter 13. A hook 121 is protruded inwardly towards a mid-section area of the second internal diameter 12, and an internal thread 131 is formed at a mid-section area of the third internal diameter 13, and a through hole 132 is formed at the insulating sheath 10 on an external side of the internal thread 131 and interconnected to the third internal diameter 13, and a protruding ring 14 is protruded from the exterior of the insulating sheath 10 and disposed at a position corresponding to the internal thread 131.

The conductive wire 20 is comprised of a bare wire 21 and an enameled wire 22 covered on an external surface of the bare wire 21, and the conductive wire 20 is passed through an end of the first internal diameter 11 of the insulating sheath 10 and connected into the insulating sheath 10.

In FIG. 2, the complex probe tip 30 includes a connecting section 31 and extended in opposite directions from both ends of the connecting section 31 respectively, a first measuring head 32 and a second measuring head 33. The connecting section 31 is made of an insulating material such as plastic, and the first external thread 311 and the second external thread 312 are formed at a mid-section area of the connecting section 31 and screwed with the internal thread 131, and a positioning pillar 313 is protruded from an interval between the first external thread 311 and the second external thread 312. The first measuring head 32 and the second measuring head 33 are integrally formed and electrically connected to each other, and each measuring head 32, 33 is comprised of a straight rod section 321, 331 and a tip 322, 332, and a first insulating sheath 323 (European specification) is completely covered onto the external surface of the straight rod section 321 of the first measuring head 32, and a second insulating sheath 333 (non-European specification) is partially covered onto the external surface of the straight rod section 331 of the second measuring head 33, and the first measuring head 32 and the second measuring head 33 can be measuring heads of two different specifications or the same specification.

In a preferred embodiment, the test probe further comprises an elastic connector 40 for electrically connecting the conductive wire 20 and the complex probe tip 30, and the elastic connector 40 includes a conducting terminal 41, a piston 42, a compression spring 43 and a cap 44, wherein each of the aforementioned components is made of a conductive material, and an end of the conducting terminal 41 is clamped and connected to the bare wire 21, and a tube body is formed at another end of the conducting terminal 41 for passing and connecting the piston 42, and the compression spring 43 is connected between the piston 42 and the cap 44, and a hook portion 441 is formed at the external periphery of the cap 44 and latched and fixed with the hook 121, and a pit 442 is stamped and formed at a distal portion of the cap 44 for embedding and fixing each of the tips 322, 332.

During the assembling process, the conductive wire 20 is passed into an end of the first internal diameter 11 of the insulating sheath 10 and then passed out from an end of the third internal diameter 13, and the conducting terminal 41 is clamped onto the bare wire 21, and an end of the piston 42 is passed and fixed to the conducting terminal 41. After the cap 44 is passed and connected to an end of the compression spring, another end of the compression spring 43 is sheathed on the piston 42 and then a tool (not shown in the figure) is used to push the cap 44 into the second internal diameter 12 of the insulating sheath 10, and latch and fix the hook portion 441 of the cap 44 onto an internal side of the hook 121.

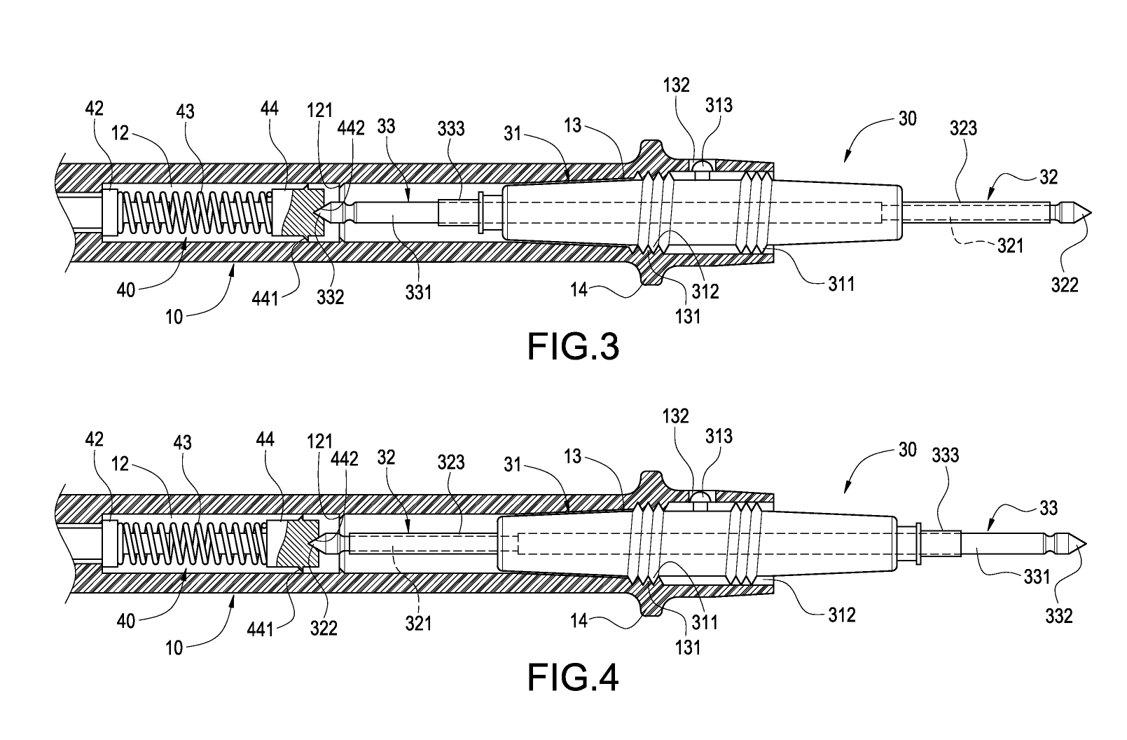

In FIGS. 3 and 4, each of the external threads 311, 312 of the connecting section 31 can be selectively combined with the internal thread 131 of the insulating sheath 10, such that if the second external thread 312 of the connecting section 31 is aligned precisely and screwed with the internal thread 131 of the insulating sheath 10, the tip 332 of the second measuring head 33 will be embedded into the pit 442 of the cap 44 to push the hook portion 441 of the cap 44 to release its positioning relation with the hook 121 and move towards the piston 42. In addition, the positioning pillar 313 is embedded precisely and latched to the through hole 132 of the insulating sheath 10. Now, the first measuring head 32 is exposed from the insulating sheath 10, and the second measuring head 33 is electrically connected to the conductive wire 20 (as shown in FIG. 3), so that the first measuring head 32 can be used for measuring numeric values of voltage, current and resistance of various types of electric products. Similarly, if the first external thread 311 of the connecting section 31 is aligned precisely and screwed with the internal thread 131 of the insulating sheath 10, the tip 322 of the first measuring head 32 can be embedded into the pit 442 of the cap 44 to push the hook portion 441 of the cap 44 to release its positioning relation with the hook 121 and move towards the piston 42. In addition, the positioning pillar 313 is embedded precisely and latched into the through hole 132 of the insulating sheath 10, and the second measuring head 33 is exposed from the insulating sheath 10, and the first measuring head 32 is electrically connected to the conductive wire 20 (as shown in FIG. 4), so that the second measuring head 33 can be used for measuring numeric values including the voltage, current and resistance of various types of electric products.

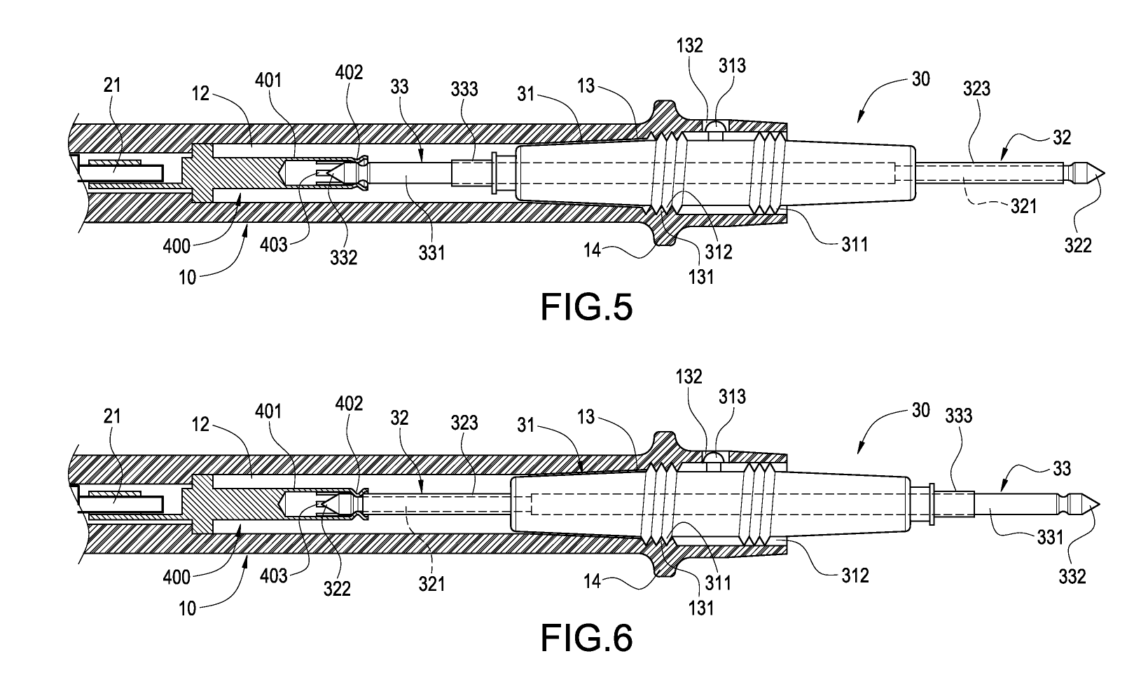

With reference to FIGS. 5 and 6 for another preferred embodiment of the present invention, the connector 400 has an end clamped onto the bare wire 21, a tube body 401 disposed at another end of the connector 400, a tapered neck section 402 formed at an end of the tube body 401, and a plurality of cut grooves 403 formed on the tapered neck section 402.

When use, the second external thread 312 of the connecting section 31 is aligned precisely and screwed with the internal thread 131 of the insulating sheath 10, and the tip 332 of the second measuring head 33 is inserted into the tube body 401 and elastically clamped by the tapered neck section 402, and the positioning pillar 313 is embedded precisely and latched into the through hole 132 of the insulating sheath 10. Now, the first measuring head 32 is exposed from the insulating sheath 10, and the second measuring head 33 is electrically connected to the conductive wire 20 (as shown in FIG. 5). Similarly, the first external thread 311 of the connecting section 31 is aligned precisely and screwed with the internal thread 131 of the insulating sheath 10, and the tip 322 of the first measuring head 32 is inserted into the tube body 401 and elastically clamped by the tapered neck section 402. In addition, the positioning pillar 313 is embedded precisely and embedded into the through hole 132 of the insulating sheath 10. Now, the second measuring head 33 is exposed from the insulating sheath 10, and the first measuring head 32 is electrically connected to the conductive wire 20 (as shown in FIG. 6).

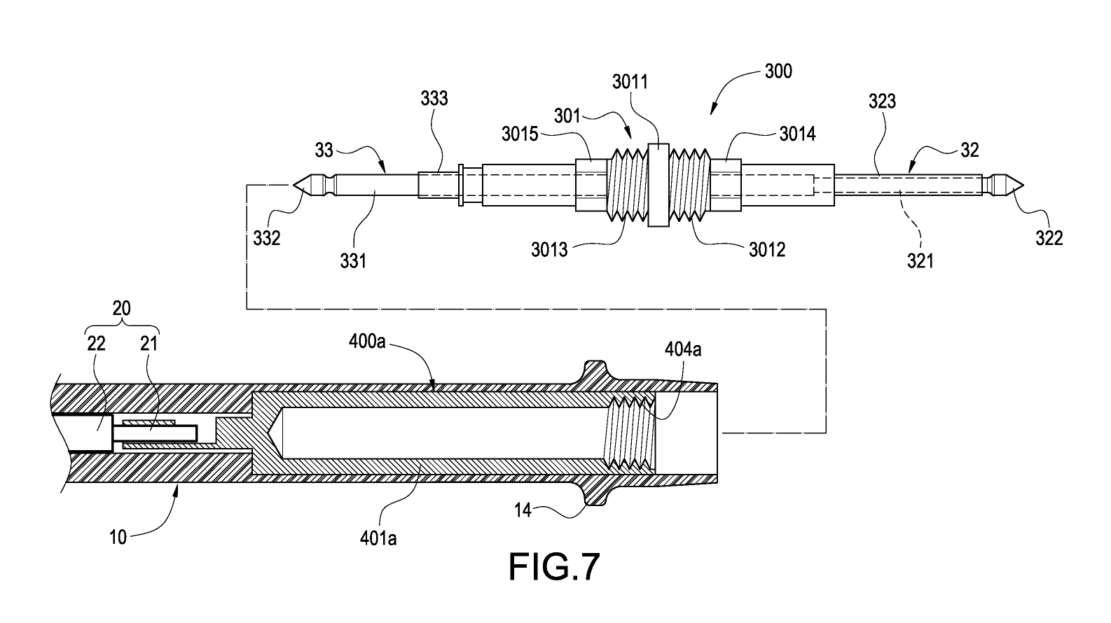

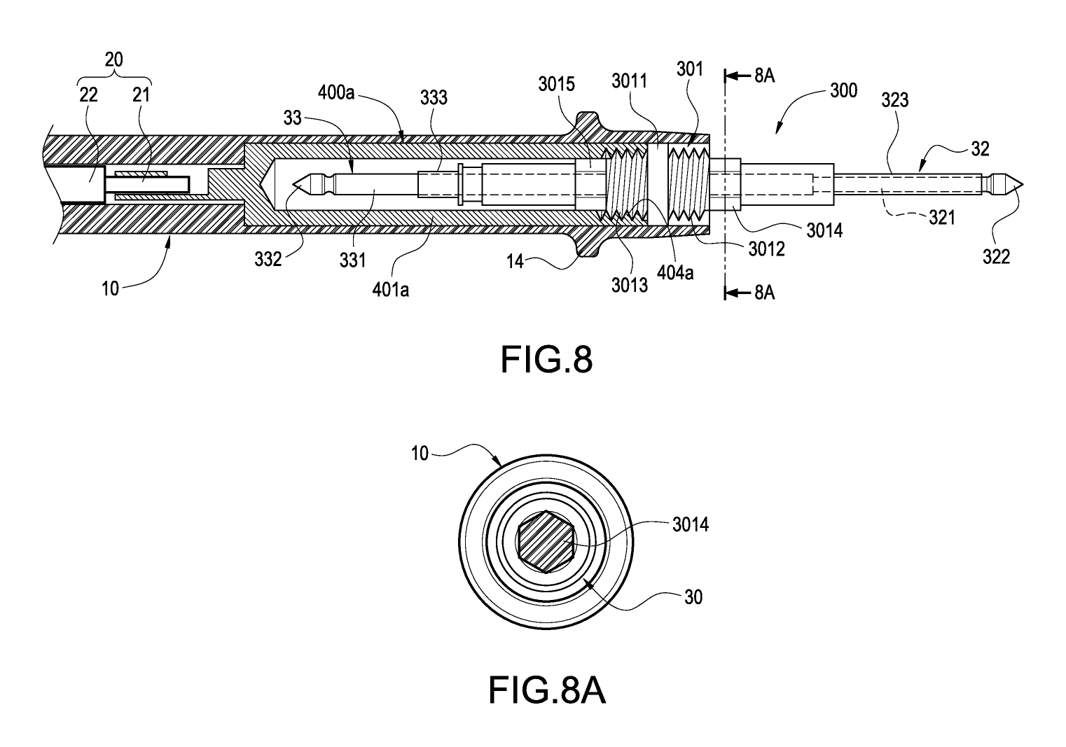

With reference to FIGS. 7 to 9, an end of the connector 400a of the present invention can be clamped onto the bare wire 21, and a tube body 401a is disposed at another end of the connector 400a, and an internal thread 404a is formed at an end of the tube body 401a. In addition, a partition plate 3011 is installed at a position of the connecting section 301 of the complex probe tip 300, and a first external thread 3012 and a second external thread 3013 are formed on both edges of the partition plate 3011 respectively, wherein the partition plate 3011, first external thread 3012 and second external thread 3013 are made of an electrically conductive material, and the partition plate 3011 is electrically conductively connected with the first measuring head 32 and the second measuring head 33, and two polygonal lumps 3014, 3015 are formed on external sides of the first external thread 3012 and the second external thread 3013 respectively, and the polygonal lumps of this preferred embodiment (as shown in FIG. 8A) are provided for connecting and rotating a tool such as a wrench.

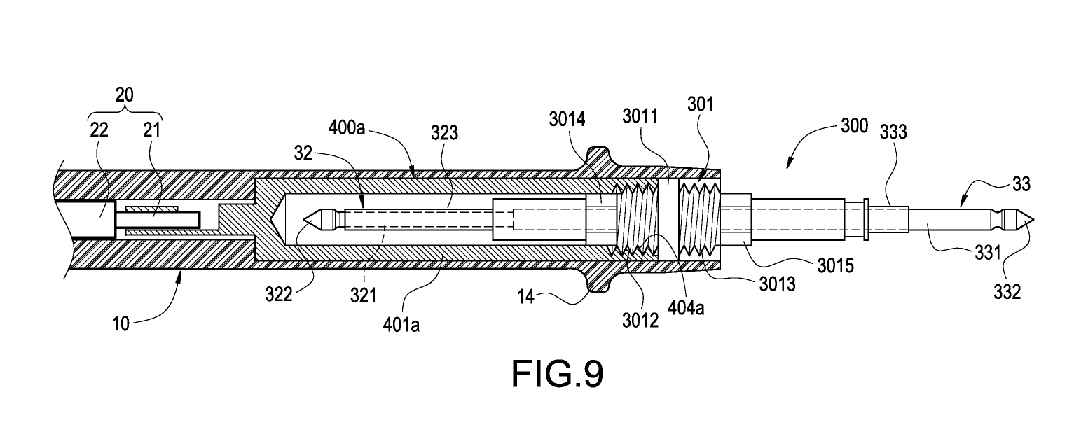

When use, the second external thread 3013 of the connecting section 301 is aligned precisely with the internal thread 404a of the connector 400a. Since the first and second external threads 3012, 3013 are electrically conductively connected with the first measuring head 32 and the second measuring head 33, and the first measuring head 32 is exposed from the insulating sheath 10, the second measuring head 33 is electrically conductively coupled to the conductive wire 20 through the connector 400a (as shown in FIG. 8). Similarly, the first external thread 3012 of the connecting section 301 is aligned precisely and screwed with the internal thread 404a of the connector 400a. Now, the second measuring head 33 is exposed from the insulating sheath 10, and the first measuring head 32 is electrically conductively connected to the conductive wire 20 through the connector 400a (as shown in FIG. 9).

In summation of the description above, the present invention improves over the prior art and complies with the patent application requirements, and thus is duly filed for patent application. While the invention has been described by means of specific embodiments, numerous modifications and variations could be made thereto by those skilled in the art without departing from the scope and spirit of the invention set forth in the claims.

What is claimed is:

1. A test probe with a dual switching probe tip, comprising:
an insulating sheath;
a conductive wire, with an end passed and coupled into the insulating sheath; and
a complex probe tip, having a connecting section, and a first measuring head and a second measuring head extended in opposite directions from both ends of the connecting section respectively, and the first measuring head and the second measuring head being electrically coupled to each other, and the first measuring head and the second measuring head being measuring heads of two different specifications, and the connecting section being selectively combined with the insulating sheath, and the first measuring head being exposed from the insulating sheath or accommodated in the insulating sheath and electrically coupled to the conductive wire.

2. The test probe with a dual switching probe tip as recited in claim 1, wherein the insulating sheath includes an internal thread formed therein, and the connecting section includes a first external thread and a second external thread separately screwed with the internal thread.

3. The test probe with a dual switching probe tip as recited in claim 1, wherein the insulating sheath includes a through hole, and the connecting section includes a positioning pillar protruded from the connection section and disposed at a position corresponding to the through hole, such that the positioning pillar can be embedded and fixed into the through hole.

4. The test probe with a dual switching probe tip as recited in claim 1, wherein the first measuring head includes a straight rod section, a tip extended from the straight rod section, and a first insulating sheath provided for completely covering the external surface of the straight rod section.

5. The test probe with a dual switching probe tip as recited in claim 1, wherein the second measuring head includes a straight rod section, a tip extended from the straight rod section, and a second insulating sheath provided for partially covering the external surface of the straight rod section.

6. The test probe with a dual switching probe tip as recited in claim 1, further comprising an elastic connector for electrically coupling the conductive wire to the complex probe tip.

7. The test probe with a dual switching probe tip as recited in claim 6, wherein the elastic connector includes a conducting terminal, a piston, a compression spring and a cap, and an end of the conducting terminal is coupled to another end of the conductive wire for passing and connecting the piston, and the compression spring is connected between the piston and the cap.

8. The test probe with a dual switching probe tip as recited in claim 7, wherein the cap includes a hook portion formed at an external periphery of the cap, and the insulating sheath includes a hook protruded from the interior of the insulating sheath and latched with the hook portion, and the cap includes a pit stamped and formed at a distal portion of the cap, and each of the first and second measuring heads has a tip, and the pit is provided for embedding and positioning the tips.

9. The test probe with a dual switching probe tip as recited in claim 6, wherein the elastic connector includes a tube body disposed at an end of the elastic connector, a tapered neck section formed at an end of the tube body, and a plurality of cut grooves formed at the tapered neck section, and the first measuring head or a second measuring head passed and connected to the tube body is elastically clamped by the tapered neck section.

10. The test probe with a dual switching probe tip as recited in claim 1, further comprising a connector with an end coupled to the conductive wire, and another end having a tube body; an internal thread formed at an end of the tube body, and the connecting section being a conductor and having a first external thread and a second external thread electrically conductively screwed with the internal thread.

11. The test probe with a dual switching probe tip as recited in claim 10, wherein the first and second external threads include a plurality of polygonal lumps formed on external sides of the first and second external threads respectively.

12. A test probe with a dual switching probe tip, comprising:
an insulating sheath;
a conductive wire, with an end passed and coupled into the insulating sheath; and
a complex probe tip, having a connecting section, and a first measuring head and a second measuring head extended in opposite directions from both ends of the connecting section respectively, and the first measuring head and the second measuring head being electrically coupled to each other, and the connecting section being selectively combined with the insulating sheath, and the first measuring head being exposed from the insulating sheath or accommodated in the insulating sheath, and electrically coupled to the conductive wire.

13. The test probe with a dual switching probe tip as recited in claim 12, wherein the insulating sheath includes an internal thread formed therein, and the connecting section includes a first external thread and a second external thread separately screwed with the internal thread.

14. The test probe with a dual switching probe tip as recited in claim 12, wherein the insulating sheath includes a through hole, and the connecting section includes a positioning pillar protruded from the connection section and disposed at a position corresponding to the through hole, such that the positioning pillar can be embedded and fixed into the through hole.

15. The test probe with a dual switching probe tip as recited in claim 12, further comprising an elastic connector for electrically coupling the conductive wire to the complex probe tip.

16. The test probe with a dual switching probe tip as recited in claim 15, wherein the elastic connector includes a conducting terminal, a piston, a compression spring and a cap, and an end of the conducting terminal is coupled to another end of the conductive wire for passing and connecting the piston, and the compression spring is connected between the piston and the cap.

17. The test probe with a dual switching probe tip as recited in claim 16, wherein the cap includes a hook portion formed at an external periphery of the cap, and the insulating sheath includes a hook protruded from the interior of the insulating sheath and latched with the hook portion, and the cap includes a pit stamped and formed at a distal portion of the cap, and each of the first and second measuring heads has a tip, and the pit is provided for embedding and positioning the tips.

18. The test probe with a dual switching probe tip as recited in claim 15, wherein the elastic connector includes a tube body disposed at an end of the elastic connector, a tapered neck section formed at an end of the tube body, and a plurality of cut grooves formed at the tapered neck section, and the first measuring head or a second measuring head passed and connected to the tube body is elastically clamped by the tapered neck section.

19. The test probe with a dual switching probe tip as recited in claim 12, further comprising a connector with an end coupled to the conductive wire, and another end having a tube body, and an internal thread formed at an end of the tube body, and the connecting section being a conductor and having a first external thread and a second external thread electrically conductively screwed with the internal thread.

20. The test probe with a dual switching probe tip as recited in claim 19, wherein the first and second external threads include a plurality of polygonal lumps formed on external sides of the first and second external threads respectively.
